(19) United States
(12) Patent Application Publication
(10) Pub. No.: US 2014/0103359 A1
(43) Pub. Date: Apr. 17, 2014

(54) SEMICONDUCTOR LIGHT-EMITTING DEVICE AND METHOD FOR MANUFACTURING SAME

(71) Applicants: Hyun Wook Shim, Suwon-si, Gyunggi-do (KR); Sang Heon Han, Suwon-si, Gyunggi-do (KR); Jae Woong Han, Seongnam-si, Gyunggi-do (KR); Dong Chul Shin, Geoje-si, Gyeongsangnam-do (KR); Je Won Kim, Seoul (KR); Dong Ju Lee, Suwon-si, Gyunggi-do (KR)

(72) Inventors: Hyun Wook Shim, Suwon-si, Gyunggi-do (KR); Sang Heon Han, Suwon-si, Gyunggi-do (KR); Jae Woong Han, Seongnam-si, Gyunggi-do (KR); Dong Chul Shin, Geoje-si, Gyeongsangnam-do (KR); Je Won Kim, Seoul (KR); Dong Ju Lee, Suwon-si, Gyunggi-do (KR)

(73) Assignee: SAMSUNG ELECTRONICS CO., LTD., Suwon-si, Gyeonggi-do (KR)

(21) Appl. No.: 14/125,878

(22) PCT Filed: Jul. 28, 2011
(86) PCT No.: PCT/KR2011/005570

§ 371 Date: Dec. 12, 2013

(51) Int. Cl. H01L 33/32; H01L 33/00

(52) U.S. Cl. CPC H01L 33/32; H01L 33/0075
USPC 257/76; 438/46

(57) ABSTRACT

A semiconductor light emitting device having enhanced luminous efficiency and a manufacturing method thereof are provided. The semiconductor light emitting device includes: an n-type semiconductor layer having at least one pit formed in an upper surface thereof; an active layer formed on the n-type semiconductor layer, a region of the active layer corresponding to the pit having an upper surface bent along the pit; and a p-type semiconductor layer formed on the active layer, a region of the p-type semiconductor layer corresponding to the pit having an upper surface bent along the bent portion of the active layer.

### BACKGROUND OF THE INVENTION

1. Field of the Invention

The present invention relates to a semiconductor light emitting device and, more particularly, to a semiconductor light emitting device having enhanced light extraction efficiency and a manufacturing method thereof.

2. Description of the Related Art

The utility of a nitride semiconductor light emitting device, a light emitting device capable of generating light having a wide range of wavelength bands, including monochromatic light such as blue, green, or the like, by using the principle of electron-hole recombination, has extended into relevant technical sectors in which it may be applied to a backlight unit (BLU), an electronic device, a general illumination device, or the like, requiring a high current/high output, beyond the existing simple display or portable liquid crystal display markets. Also, according to this trend, a nitride semiconductor light emitting device is required to have high degree of luminance and a high degree of reliability.

Thus, in order to enhance luminous efficiency, a method for restraining carriers moving to a non-light emitting center and raising a carrier probability density of a light emitting center has been studied. However, in the case of a nitride semiconductor light emitting device, a lattice constant and thermal expansion coefficient thereof are significantly different from those of a sapphire substrate largely used as a growth substrate, generating a large number of defects in a grown nitride semiconductor. Such defects act as non-light emitting centers. In order to reduce such defects, a lateral growth technique using a mask has been proposed, but this technique involves removing a wafer (from a growth chamber) and performing patterning thereon during a growth process, causing inconvenience in the process and increasing manufacturing costs. While this method substantially reduces the number of crystal defects, it lacks an ability to prevent crystal defects from acting as non-light emitting centers.

### SUMMARY OF THE INVENTION

An aspect of the present invention provides a semiconductor light emitting device having increased internal quantum efficiency by increasing radiative recombination by using a pit formed in a semiconductor layer, and having enhanced luminous efficiency by increasing external extraction efficiency through a slope of the pit.

Another aspect of the present invention provides a method for manufacturing a semiconductor light emitting device allowing for the foregoing semiconductor light emitting device to be easily manufactured.

According to an aspect of the present invention, there is provided a semiconductor light emitting device including: an n-type semiconductor layer having at least one pit formed in an upper surface thereof; an active layer formed on the n-type semiconductor layer, a region of the active layer corresponding to the pit having an upper surface bent along the pit; and a p-type semiconductor layer formed on the active layer, a region of the p-type semiconductor layer corresponding to the pit having an upper surface bent along the bent portion of the active layer.

The upper surfaces of the active layer and the p-type semiconductor layer may have a first region curved toward the pit and a second region which is uncurved.

An energy band gap of the first region of the active layer may be greater than that of the second region.

The upper surface of the n-type semiconductor layer may have sloped surfaces formed by the pit and a flat surface formed between the sloped surfaces.

The pit may have a surface sloped downwardly toward the n-type semiconductor layer.

The pit may have a shape of an inverted pyramid.

The upper surface of the n-type semiconductor layer may be plane (0001).

The sloped surface of the pit may be plane (1101).

The n-type semiconductor layer, the active layer, and the p-type semiconductor layer may be made of a nitride semiconductor, and the n-type semiconductor layer may include an n-type GaN contact layer having an n-type impurity doped therein and an undoped GaN semiconductor layer formed on the n-type GaN contact layer and having at least one pit formed in an upper surface thereof.

The semiconductor light emitting device may further include: a substrate formed on a lower surface of the n-type semiconductor layer; and electrodes electrically connected to the n-type semiconductor layer and the p-type semiconductor layer, respectively.

According to another aspect of the present invention, there is provided a method for manufacturing a semiconductor light emitting device including: forming an n-type semiconductor layer having at least one pit formed in an upper surface thereof; forming an active layer having an upper surface bent along the pit on the n-type semiconductor layer; and forming a p-type semiconductor layer on the active layer such that a region of the p-type semiconductor layer corresponding to the pit has an upper surface bent along the bent portion of the active layer.

The forming of the active layer and the p-type semiconductor layer may be performed such that the respective upper surfaces of the active layer and the p-type semiconductor layer may have a first region curved toward the pit and a second region which is uncurved.

In the forming of the n-type semiconductor layer, the pit may be spontaneously formed during a process of forming the n-type semiconductor layer.

The forming of the n-type semiconductor layer may include: forming an n-type GaN contact layer having an n-type impurity doped therein on the substrate; and forming an undoped GaN semiconductor layer having at least one pit formed in an upper surface thereof on the n-type GaN contact layer.

The method may further include: forming electrodes electrically connected to the n-type semiconductor layer and the p-type semiconductor layer, respectively.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically illustrating a light emitting structure according to an embodiment of the present invention.

FIG. 2 is a perspective view schematically illustrating a pit structure of FIG. 1;

FIG. 3 is an enlarged detailed view of a peripheral region ‘A’ of the pit structure of FIG. 1;

FIG. 4 is a cross-sectional view schematically illustrating a direction in which light is emitted from the pit structure of FIG. 1;

FIG. 5 is a cross-sectional view schematically showing a semiconductor light emitting structure according to a first embodiment of the present invention;

FIGS. 6 through 8 are cross-sectional views illustrating respective processes of a method for manufacturing a semiconductor light emitting device according to the first embodiment of the present invention;

FIG. 9 is a cross-sectional view schematically showing a semiconductor light emitting structure according to a second embodiment of the present invention; and

FIGS. 10 through 12 are cross-sectional views illustrating respective processes of a method for manufacturing a semiconductor light emitting device according to the second embodiment of the present invention.

### DETAILED DESCRIPTION OF THE PREFERRED EMBODIMENT

Embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

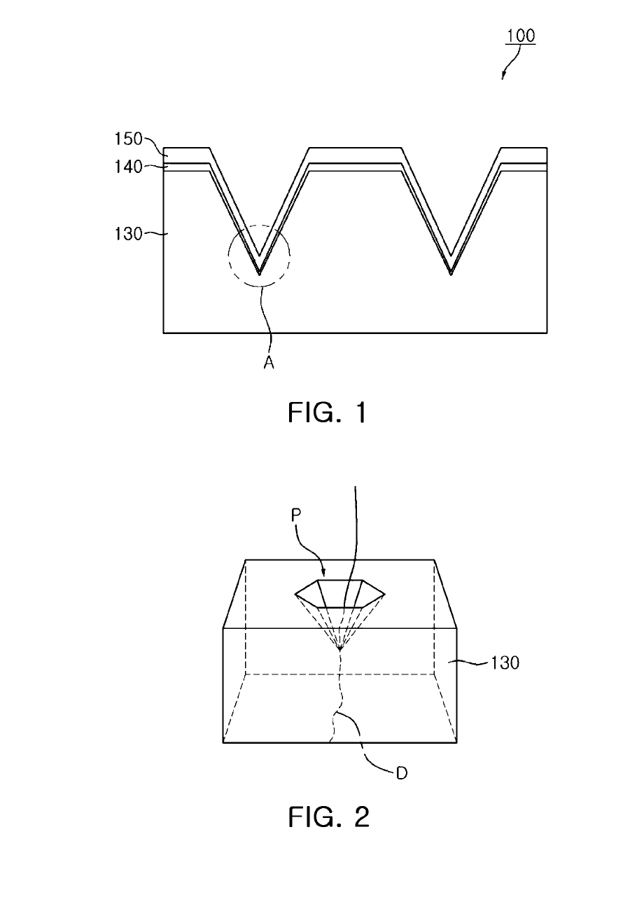

FIG. 1 is a cross-sectional view schematically illustrating a light emitting structure according to an embodiment of the present invention. As illustrated in FIG. 1, a light emitting structure 100 according to the present embodiment includes an n-type semiconductor layer 130, a p-type semiconductor layer 150, and an active layer 140 formed therebetween. The uppermost surface of the light emitting structure 100 includes flat surfaces and sloped surfaces. Namely, the uppermost surface of the light emitting structure 100 has pits formed as the upper surfaces are sloped downwardly to the n-type semiconductor layer 130.

Here, the n-type and p-type semiconductor layers 130 and 150 may be made of a nitride semiconductor, namely, a semiconductive material doped with an n-type impurity and a p-type impurity having an empirical formula AlₓIn_{y}Ga_{(1-x-y)}N (here, 0≦x≦1, 0≦y≦1, 0≦x+y≦1), and the semiconductive material may be, typically, GaN, AlGaN, and InGaN. Silicon (Si), germanium (Ge), selenium (Se), tellurium (Te), or the like, may be used as the n-type impurity, and manganese (Mg), zinc (Zn), beryllium (Be), or the like, may be used as the p-type impurity. The n-type and p-type semiconductor layers 130 and 150 may be grown through a process commonly known in the art, such as metal-organic chemical vapor deposition (MOCVD), hydride vapor phase epitaxy (HVPE), molecular beam epitaxy (MBE), and the like. Thus, the active layer 140 formed between the n-type and p-type semiconductor layers emits light having a certain level of energy according to a radiative recombination of electrons and holes, and may be made of a material such as InₓGa₁₋ₓN (0≦x≦1) so that a band gap energy can be adjusted according to the content of indium. For example, the active layer 140 may have a multi-quantum well structure in which InGaN quantum well layers and GaN quantum barrier layers are alternately laminated. Here, the quantum barrier layer may have a super-lattice structure having a thickness allowing for holes injected from the p-type semiconductor layer 150 to be tunneled. The quantum barrier layer may be made of AlₓIn_{y}Ga_{(1-x-y)}N (0≦x≦1, 0<y≦1, 0<x+y≦1), and the quantum well layer may be made of In_{z}Ga_{(1-z)}N (0≦z≦1). Namely, a wavelength of light or quantum efficiency of the active layer 140 may be adjusted by adjusting the height of the quantum barrier layer, the thickness and composition of the quantum well layer, and the number of quantum wells.

In the light emitting structure 100 according to an embodiment of the present invention, at least one pit structure may be formed on the upper surface of the n-type semiconductor layer 130. Also, the active layer 140 and the p-type semiconductor layer 150 are formed to have the pit structure. Namely, a plurality of pits are formed on the uppermost surface of the light emitting structure 100 such that a width thereof narrows in a depth direction. Due to the presence of the plurality of pits, light proceeding in a horizontal direction due to internal total reflection included in light generated from the active layer may be discharged to the outside, and accordingly, light extraction efficiency can be enhanced. A schematic view of the direction in which light proceeds is illustrated in FIG. 4.

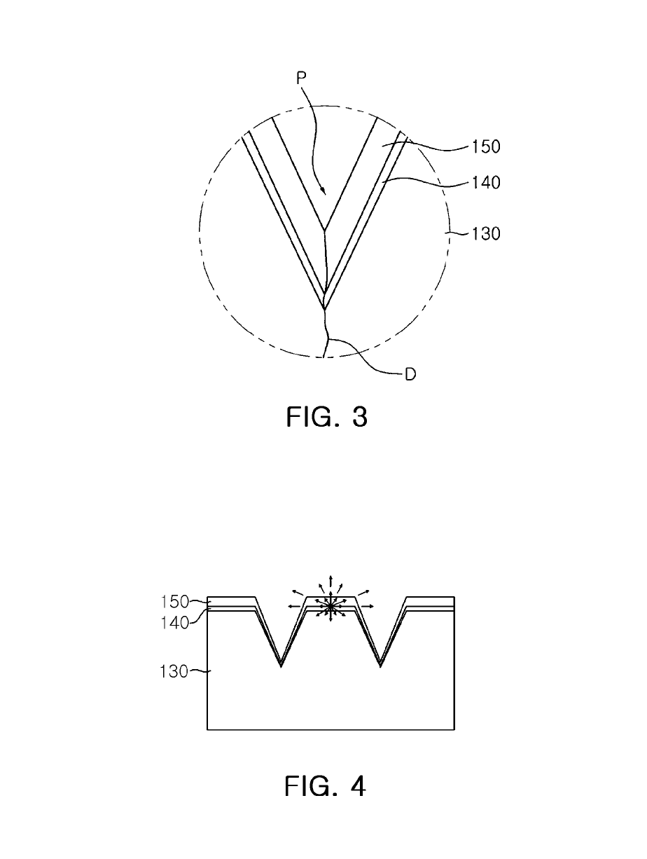

FIG. 2 is a perspective view schematically illustrating a pit structure of FIG. 1, and FIG. 3 is an enlarged detailed view of a peripheral region ‘A’ of the pit structure of FIG. 1.

As illustrated in FIG. 2, a pit P is formed to have a V-shape on an upper surface of the n-type semiconductor layer 130, and specifically, the pit may be formed in the shape of an inverted pyramid having a polygonally-shaped base forming a hexagonal pyramid, or the like. When the upper surface of the n-type semiconductor layer 130 is a flat growth surface (0001), the pit P has a sloped growth surface (1101) in relation to the upper surface of the n-type semiconductor layer 130. Namely, the n-type semiconductor layer 130 has a surface configuration including both the flat growth surface (0001) and the sloped growth surface (1101). When viewed from above the pit P has a regular hexagonal shape, and when viewed in cross-section, the pit P has a V-like shape.

The pit P may be formed by growing the n-type semiconductor layer 130 and subsequently etching an upper surface of the n-type semiconductor layer 130, but as shown in FIG. 3, the pit P may be spontaneously formed in the vicinity of a threading dislocation D of the n-type semiconductor layer 130 by appropriately adjusting conditions such as a growth speed, a growth temperature, and the like. For example, the pit may be more actively grown at a relatively low temperature. Namely, the pit P may be selectively generated in a portion where the threading dislocation D penetrating the light emitting structure 100 is formed, and through which, a phenomenon in which a current is concentrated on the threading dislocation D may occur, thereby preventing concentration of a current on the threading dislocation D.

As shown in FIG. 3, in the present embodiment, the active layer 140 and the p-type semiconductor layer 150 are formed on the n-type semiconductor layer 130, and regions of the upper surface of the active layer 140 and the p-type semiconductor layer 150 corresponding to the pit P are bent according to a shape of the pit and formed to be curved toward the pit. Namely, the active layer 140 and the p-type semiconductor layer 150 also have a pit structure having the V-shape sloped surface as that of the pit P of the n-type semiconductor layer 130.

Here, the active layer 140 and the p-type semiconductor layer 150 are formed such that a thickness of a portion formed on the sloped surface of the pit P is smaller than a thickness of a portion formed on the flat growth surface thereof. Thus, an energy band gap of the active layer 140 on the sloped region of the pit P is relatively increased in comparison to the flat region, blocking carriers from moving to a non-light emitting region such as the threading dislocation D to thus enhance recombination efficiency in the active layer 140.

FIG. 4 is a cross-sectional view schematically illustrating a direction in which light is emitted in the pit structure of FIG. 1. As illustrated in FIG. 4, sloped surfaces of the pit are non-light emitting regions, and the active layer 140 formed on the flat upper surface (0001) is a light emitting region. Thus, the light emitting structure 100 according to an embodiment of the present invention is formed to have a structure in which the uppermost surfaces include the flat surface and the surfaces sloped downwardly toward the n-type semiconductor layer 130, whereby light proceeding in the horizontal direction of light generated from the active layer 140 is emitted from the sloped surfaces to the outside as is, and thus, the amount of light that becomes extinct by internal total reflection can be reduced.

A semiconductor light emitting device using the light emitting structure having the foregoing structure will be described.

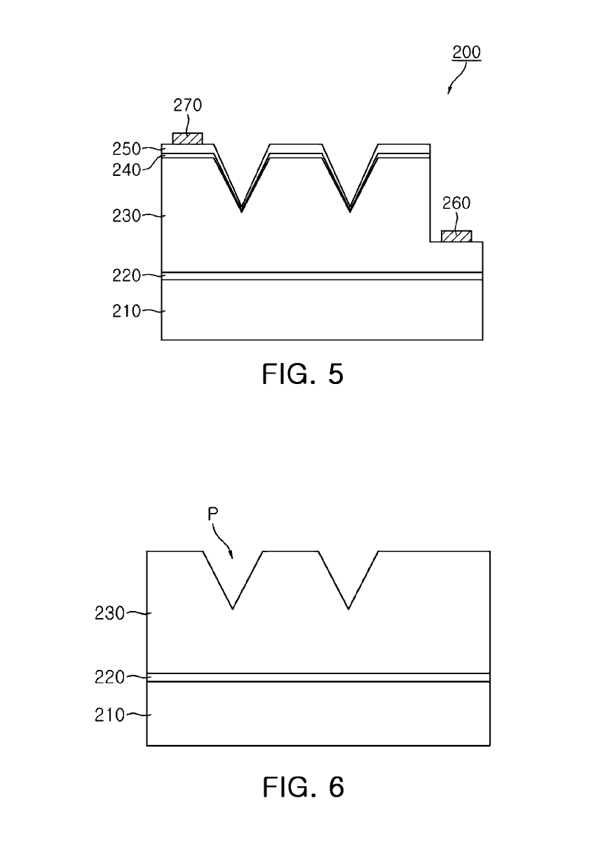

FIG. 5 is a cross-sectional view schematically showing a semiconductor light emitting structure according to a first embodiment of the present invention. Here, a light emitting device 200 according to the first embodiment illustrated in FIG. 5 employs the light emitting structure of FIG. 1 and is different from the light emitting device 100 in that it further includes a growth substrate, a buffer layer, and an electrode. Thus, a description of the light emitting structure having the same configuration will be omitted, and only a different configuration will be described.

As illustrated in FIG. 5, the semiconductor light emitting device 200 according to the first embodiment of the present invention includes a substrate 210, a buffer layer 220, a light emitting structure, an n-type electrode 260, and a p-type electrode 270. Here, the light emitting structure is the same as the light emitting structure illustrated in FIG. 1, and includes an n-type semiconductor layer 230, a p-type semiconductor layer 250, and an active layer 240 formed therebetween.

The substrate 210 is a growth substrate for growing a semiconductor single crystal, especially, a nitride single crystal, and a substrate made of a material such as sapphire, Si, ZnO, GaAs, SiC, MgAl₂O₄, MgO, LiAlO₂, LiGaO₂, GaN, or the like, may be used as the substrate 210. In this case, sapphire is a crystal having Hexa-Rhombo R3c symmetry, of which lattice constants in c-axis and a-axis directions are 13.001 Å and 4.758 Å, respectively. A sapphire crystal has a C-plane (0001), an A-plane (1120), an R-plane (1102), and the like. In this case, a nitride thin film can be relatively easily formed on the C-plane of the sapphire crystal, and because sapphire crystal is stable at high temperatures, in particular, it is commonly used as a material for a nitride growth substrate.

The buffer layer 220 is formed on the substrate 210 in order to reduce lattice mismatch between the substrate 210 and the n-type semiconductor layer 230, and may be a low-temperature nucleation layer including AlN or GaN. The buffer layer 220 may be omitted as necessary.

Partial regions of the active layer 240 and the p-type semiconductor layer 250 of the light emitting structure are mesa-etched, an n-type electrode 260 is formed on an exposed upper surface of the n-type semiconductor layer 230. Also, a p-type electrode 270 is formed on an upper surface of the p-type semiconductor layer 250.

FIGS. 6 through 8 are cross-sectional views illustrating respective processes of a method for manufacturing a semiconductor light emitting device according to the first embodiment of the present invention illustrated in FIG. 5. Here, a description of the same configuration as that of FIGS. 1 and 5 will be omitted.

First, as illustrated in FIG. 6, the buffer layer 220 and the n-type semiconductor layer 230 having at least one pit P formed on an upper surface thereof are sequentially formed on the growth substrate 210. Here, the n-type semiconductor layer 230 may be grown through a process such as MOCVD, MBE, HVPE, or the like, and the pit P may be formed through etching, or the like, but preferably, the pit P is spontaneously formed in the vicinity of a threading dislocation through, for example, a low temperature growth by appropriately adjusting conditions such as a growth speed, a growth temperature, and the like.

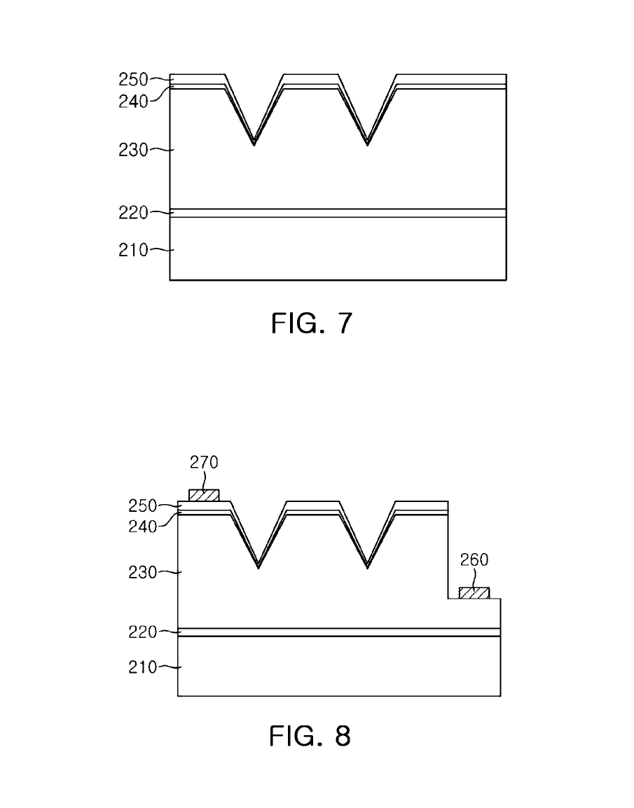

Subsequently, as shown in FIG. 7, the active layer 240 and the p-type semiconductor layer 250 are sequentially formed on the n-type semiconductor layer 230. Here, the active layer 240 and the p-type semiconductor layer 250 are formed to have a bent upper surface according to the shape of the pit P. Namely, upper surfaces of the regions corresponding to the pit P of the active layer 240 and the p-type semiconductor layer 250 are curved toward the sloped surfaces of the pit P, and the portions formed on the sloped surfaces are thinner than the portions formed on the flat surfaces. Thus, the region of the active layer 240 formed on the sloped surface of the pit P has a higher energy band gap than that of the region formed on the flat surface, blocking carriers from moving to the pit P, a non-light emitting center.

Next, as illustrated in FIG. 8, partial regions of the active layer 240 and the p-type semiconductor layer 250 of the light emitting structure are mesa-etched to expose the n-type semiconductor layer 230. The n-type electrode 260 is formed on the exposed n-type semiconductor layer 230, and the p-type electrode 270 is formed on the p-type semiconductor layer 250. Although not shown, a transparent electrode made of a material such as ITO, IZO, or the like, may be further formed between the p-type semiconductor layer 250 and the p-type electrode 270 in order to enhance an ohmic-contact function.

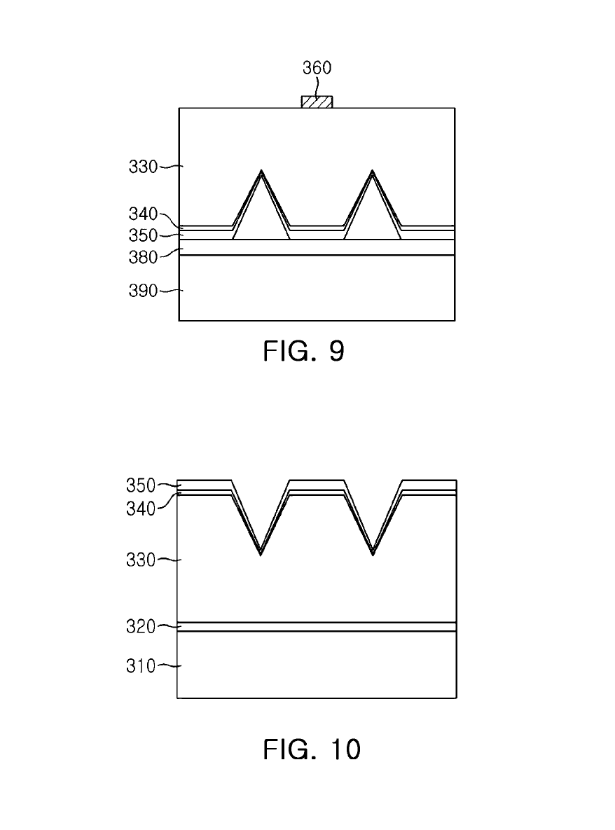

FIG. 9 is a cross-sectional view schematically showing a semiconductor light emitting structure according to a second embodiment of the present invention. Here, a light emitting device 300 according to the second embodiment illustrated in FIG. 9 employs the light emitting structure of FIG. 1 and is different from the light emitting device 100 in that it further includes a conductive substrate, a highly reflective ohmic-contact layer, and an electrode. Thus, a description of the light emitting structure having the same configuration will be omitted, and only a different configuration will be described.

As illustrated in FIG. 9, the semiconductor light emitting device 300 according to the second embodiment of the present invention includes a conductive substrate 390, a highly reflective ohmic-contact layer 380, a light emitting structure, and an n-type electrode 360. Here, the light emitting structure is the same as the light emitting structure illustrated in FIG. 1, and includes an n-type semiconductor layer 330, a p-type semiconductor layer 350, and an active layer 340 formed therebetween.

The conductive substrate 390 serves as a support supporting the light emitting structure during a process such as a laser lift-off process, or the like, as well as serving as a p-type electrode. Namely, the semiconductor single crystal growth substrate is removed through a process such as a laser lift-off process, or the like, after the removal process, the n-type electrode 360 is formed on the exposed surface of the n-type semiconductor layer 330. In this case, the conductive substrate 390 may be made of a material such as silicon (Si), copper (Cu), nickel (Ni), gold (Au), tungsten (W), titanium (Ti), and the like, or an alloy of metals selected therefrom. The conductive substrate 390 may be formed through a method such as plating, bonding, or the like.

The highly reflective ohmic-contact layer 380 performs an ohmic-contact function and a light reflecting function between the p-type semiconductor layer 350 and the conductive substrate 390. The highly reflective ohmic-contact layer 380 is not essential, so it may be omitted.

FIGS. 10 through 12 are cross-sectional views illustrating respective processes of a method for manufacturing a semiconductor light emitting device according to the second embodiment of the present invention illustrated in FIG. 9. Here, a description of the same configuration as those of FIGS. 1 and 9 will be omitted, and FIG. 10 has the same process as that illustrated in FIG. 7.

First, as illustrated in FIG. 10, the buffer layer 320, the n-type semiconductor layer 330, the active layer 340, and the p-type semiconductor layer 350 are sequentially formed on a growth substrate 310. Here, the n-type semiconductor layer 330 is formed to have at least one pit on an upper surface thereof, and the active layer 340 and the p-type semiconductor layer 350 are formed such that regions thereof corresponding to the pit have an upper surface bent along the pit.

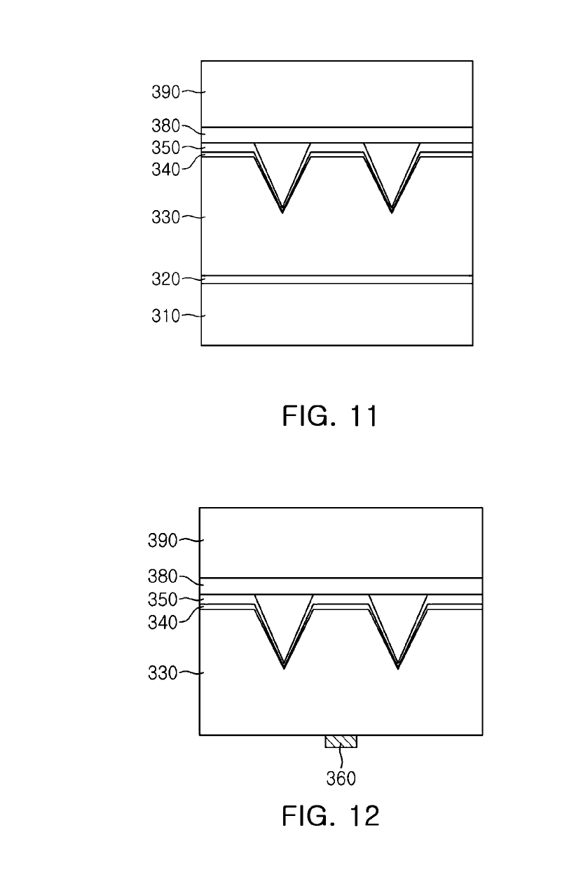

Subsequently, as illustrated in FIG. 11, the highly reflective ohmic-contact layer 380 and the conductive substrate 390 are formed on the p-type semiconductor layer 350. Here, after the highly reflective ohmic-contact layer 380 is formed on the p-type semiconductor layer 350, the conductive substrate 390 may be formed, or after the highly reflective ohmic-contact layer 380 is formed on the conductive substrate 390, the combination of the highly reflective ohmic-contact layer 380 and the conductive substrate 390 may be bonded to the p-type semiconductor layer 350.

Thereafter, as shown in FIG. 12, the growth substrate 310 is separated from the structure manufactured as illustrated in FIG. 11 by using a lift-off process, or the like, and the buffer layer 320 is removed through polishing, or the like. The n-type electrode 360 is formed on the exposed n-type semiconductor layer 330. Here, a laser lift-off (LLO) process, a mechanical or chemical lift-off process, or the like, may be used as the lift-off process. The n-type electrode 360 may be formed through metal thin film deposition using APCVD, LPCVD, PECVD, or the like, and a material made of Ni/Au, or the like, may be employed.

As described above, in the semiconductor light emitting devices 200 and 300 according to the first and second embodiments of the present invention, a pit is formed in the vicinity of a threading dislocation that penetrates the light emitting structure to increase resistance thereof, whereby a current concentrated on the threading dislocation when static electricity is applied can be interrupted. Namely, a leakage current due to the threading dislocation is prevented to thus improve electrical characteristics. Also, since an energy band gap of the sloped surfaces of the pit is increased to be greater than other regions, carriers can be prevented from moving to non-light emitting regions. Namely, internal quantum efficiency can be increased by increasing recombination efficiency of the active layer. Also, since a pit structure is formed up to the uppermost surface of the light emitting device, light generated from the active layer can be discharged through the sloped surfaces of the pit without being internally totally reflected, enhancing external extraction efficiency.

As set forth above, according to embodiments of the invention, since a pit is formed in the n-type semiconductor layer, radiative recombination can be increased, and thus, internal quantum efficiency can be increased and a leakage current can be reduced. Also, according to embodiments of the present invention, since a pit is formed up to the uppermost surface of the light emitting device, external extraction efficiency through sloped surfaces of the pit can be increased, thus enhancing luminous efficiency of the device.

While the present invention has been shown and described in connection with the embodiments, it will be apparent to those skilled in the art that modifications and variations can be made without departing from the spirit and scope of the invention as defined by the appended claims.

What is claimed is:

1. A semiconductor light emitting device comprising:
an n-type semiconductor layer having at least one pit formed in an upper surface thereof;
an active layer formed on the n-type semiconductor layer, a region of the active layer corresponding to the pit having an upper surface bent along the pit; and
a p-type semiconductor layer formed on the active layer, a region of the p-type semiconductor layer corresponding to the pit having an upper surface bent along the bent portion of the active layer.

2. The semiconductor light emitting device of claim 1, wherein the upper surfaces of the active layer and the p-type semiconductor layer have a first region curved toward the pit and a second region which is uncurved.

3. The semiconductor light emitting device of claim 2, wherein an energy band gap of the first region of the active layer is greater than that of the second region.

4. The semiconductor light emitting device of claim 1, wherein the upper surface of the n-type semiconductor layer has sloped surfaces formed by the pit and a flat surface formed between the sloped surfaces.

5. The semiconductor light emitting device of claim 1, wherein the pit has a surface sloped downwardly toward the n-type semiconductor layer.

6. The semiconductor light emitting device of claim 1, wherein the pit has a shape of an inverted pyramid.

7. The semiconductor light emitting device of claim 1, wherein the upper surface of the n-type semiconductor layer is plane (0001).

8. The semiconductor light emitting device of claim 7, wherein the sloped surface of the pit is plane (1101).

9. The semiconductor light emitting device of claim 1, wherein the n-type semiconductor layer, the active layer, and the p-type semiconductor layer are made of a nitride semiconductor, and the n-type semiconductor layer includes an n-type GaN contact layer having an n-type impurity doped therein and an undoped GaN semiconductor layer formed on the n-type GaN contact layer and having at least one pit formed in an upper surface thereof.

10. The semiconductor light emitting device of claim 1, further comprising:
a substrate formed on a lower surface of the n-type semiconductor layer; and
electrodes electrically connected to the n-type semiconductor layer and the p-type semiconductor layer, respectively.

11. A method for manufacturing a semiconductor light emitting device, the method comprising:
forming an n-type semiconductor layer having at least one pit formed in an upper surface thereof;
forming an active layer having an upper surface bent along the pit on the n-type semiconductor layer; and
forming a p-type semiconductor layer on the active layer such that a region of the p-type semiconductor layer corresponding to the pit has an upper surface bent along the bent portion of the active layer.

12. The method of claim 11, wherein the forming of the active layer and the p-type semiconductor layer is performed such that the respective upper surfaces of the active layer and the p-type semiconductor layer have a first region curved toward the pit and a second region which is uncurved.

13. The method of claim 11, wherein in the forming of the n-type semiconductor layer, the pit is spontaneously formed during a process of forming the n-type semiconductor layer.

14. The method of claim 11, wherein the forming of the n-type semiconductor layer comprises:
forming an n-type GaN contact layer having an n-type impurity doped therein on the substrate; and
forming an undoped GaN semiconductor layer having at least one pit formed in an upper surface thereof on the n-type GaN contact layer.

15. The method of claim 11, further comprising forming electrodes electrically connected to the n-type semiconductor layer and the p-type semiconductor layer, respectively.
